(19) United States
(12) Patent Application Publication
(10) Pub. No.: US 2025/0194190 A1
(43) Pub. Date: Jun. 12, 2025

(54) Substrates for Power Semiconductor Devices

(71) Applicant: Wolfspeed, Inc., Durham, NC (US)

(72) Inventors: Adam Benjamin Barkley, Chapel Hill, NC (US); Craig William Hardin, Apex, NC (US)

(21) Appl. No.: 18/537,427

(22) Filed: Dec. 12, 2023

(51) Int. Cl. H01L 29/16; H01L 21/02; H01L 29/66; H01L 29/778; H01L 29/78

(52) U.S. Cl. CPC H10D 62/8325; H01L 21/02529; H10D 12/031; H10D 30/475; H10D 30/615

(57) ABSTRACT

Semiconductor wafers, methods, and semiconductor devices are provided. In one example, a semiconductor wafer includes a polycrystalline silicon carbide substrate. The semiconductor wafer includes a wide bandgap epitaxial layer on the polycrystalline silicon carbide substrate.

### FIELD

The present disclosure relates generally to semiconductor devices, such as wide bandgap semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or gallium nitride (“GaN”) based semiconductor materials.

### SUMMARY

Aspects and advantages of embodiments of the present disclosure will be set forth in part in the following description, or may be learned from the description, or may be learned through practice of the embodiments.

One example aspect of the present disclosure is directed to a wide bandgap semiconductor wafer. The wide bandgap semiconductor wafer includes a polycrystalline silicon carbide substrate. The wide bandgap semiconductor wafer includes a wide bandgap epitaxial layer on the polycrystalline silicon carbide substrate.

Another example aspect of the present disclosure is directed to a method. The method includes providing a wide bandgap epitaxial layer on a first substrate. The method includes providing the wide bandgap epitaxial layer on a second substrate (e.g., polycrystalline silicon carbide substrate). The method includes separating the first substrate from the wide bandgap epitaxial layer such that at least a portion of the wide bandgap epitaxial layer remains on the second substrate.

Another example aspect of the present disclosure is directed to a method. The method includes providing a monocrystalline silicon carbide substrate layer on a substrate (e.g., polycrystalline silicon carbide substrate). The method includes separating a portion of the monocrystalline silicon carbide substrate layer such that at least a portion of the monocrystalline silicon carbide substrate layer remains on the substrate. The method includes providing a wide bandgap epitaxial layer on the monocrystalline silicon carbide substrate layer.

Another example aspect of the present disclosure is directed to a semiconductor device. The semiconductor device includes a polycrystalline silicon carbide substrate. The semiconductor device includes a wide bandgap epitaxial layer on the polycrystalline silicon carbide substrate. At least a portion of the wide bandgap epitaxial layer comprises a structure forming a part of a transistor or a diode.

Another example aspect of the present disclosure is directed to a wide bandgap semiconductor wafer. The wide bandgap semiconductor wafer includes a sapphire substrate. The wide bandgap semiconductor wafer includes a silicon carbide epitaxial layer on the sapphire substrate.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts an overview of an example method according to example embodiments of the present disclosure;

FIG. 2 depicts a cross-sectional view of an example semiconductor wafer according to example embodiments of the present disclosure;

FIG. 3 depicts a cross-sectional view of an example semiconductor wafer according to example embodiments of the present disclosure;

FIG. 4 depicts an overview of an example method according to example embodiments of the present disclosure;

FIG. 5 depicts a cross-sectional view of an example semiconductor wafer according to example embodiments of the present disclosure;

FIG. 6 depicts a cross-sectional view of an example semiconductor wafer according to example embodiments of the present disclosure;

FIG. 7 depicts an overview of an example method according to example embodiments of the present disclosure;

FIG. 8 depicts an overview of an example method according to example embodiments of the present disclosure;

FIG. 9 depicts an example semiconductor device according to example embodiments of the present disclosure;

FIG. 10 depicts an example semiconductor device according to example embodiments of the present disclosure; and

FIG. 11 depicts an example semiconductor device according to example embodiments of the present disclosure.

FIG. 12 depicts an example semiconductor device according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the power semiconductor devices according to example embodiments of the present disclosure may be used with any semiconductor material, such as other wide bandgap semiconductor materials, without deviating from the scope of the present disclosure. Example wide bandgap semiconductor materials include silicon carbide (e.g., 2.996 eV band gap for alpha silicon carbide at room temperature) and the Group III-nitrides (e.g., 3.36 eV band gap for gallium nitride at room temperature).

Power semiconductor devices can have a lateral structure or a vertical structure. In a device having a lateral structure, the terminals of the device (e.g., the drain, gate and source terminals for a power MOSFET device) are on the same major surface (e.g., top surface or bottom surface) of a semiconductor structure. In contrast, in a power semiconductor device having a vertical structure, at least one terminal is provided on each major surface of the semiconductor structure. For instance, in a vertical MOSFET device, the source may be on the top surface of the semiconductor structure and the drain may be on the bottom surface of the semiconductor structure, or vice versa.

Power semiconductor devices are often fabricated by performing fabrication processes on semiconductor wafers. The semiconductor wafers may include one or more epitaxial layers formed on a substrate. As used herein an “epitaxial layer” is a single-crystal semiconductor layer grown on top of a substrate using a process called epitaxial growth or epitaxy. The epitaxial layer may be deposited atom by atom and may adopt the crystal structure of the underlying substrate. An epitaxial layer may have a thickness in a range of, for instance, about 0.2 microns to about 200 microns.

A “substrate” refers to a solid semiconductor material upon which epitaxial layers are formed. A substrate may be a homogenous material, such as silicon carbide and/or sapphire and may provide mechanical support for the formation of epitaxial layers. In many examples, substrates may be provided as a semiconductor wafer on which various other layers and structures are formed. A substrate may have a thickness in a range of about 0.5 microns to about 1000 microns, or greater.

Power semiconductor devices (e.g., MOSFETs, JFETs, Schottky diodes, HEMTs) may be fabricated on a monocrystalline silicon carbide (e.g., 4H polytype) semiconductor wafer where the monocrystalline silicon carbide wafer serves as a substrate for the power semiconductor device. A significant portion of the monocrystalline silicon carbide substrate may remain as part of the power semiconductor device, even after backside grinding to final wafer thickness. Many power semiconductor devices are vertical power devices and may conduct current through the substrate. As a result, the monocrystalline silicon carbide substrate may, in some cases, add significant series resistance to the power semiconductor device and may add conduction losses to end application circuits for the power semiconductor device.

There may be a lower limit to the thickness to which a monocrystalline silicon carbide substrate may be reduced (e.g., through a grinding process) without risk of breaking during handling, such as about 60 μm in thickness to about 180 μm in thickness. Because of these lower limits, there is a limit to reachable substrate resistance and thus reachable specific on-state resistance and conduction losses for power semiconductor devices including monocrystalline silicon carbide substrates. Use of monocrystalline silicon carbide wafers may also add increased expense to production.

Aspects of the present disclosure are directed to wide bandgap semiconductor wafers that include a polycrystalline silicon carbide substrate. The wide bandgap semiconductor wafer may include a wide bandgap epitaxial layer (e.g., silicon carbide epitaxial layer and/or a Group III-nitride epitaxial layer) that has been provided on the polycrystalline silicon carbide substrate (e.g., attached to the polycrystalline silicon carbide substrate). One or more power semiconductor devices may be fabricated on the wide bandgap semiconductor wafer including the polycrystalline silicon carbide substrate.

More specifically, aspects of the present disclosure are directed to a semiconductor fabrication process that allows for the fabrication of semiconductor wafers with a wide bandgap epitaxial layer (e.g., silicon carbide epitaxial layer and/or a Group III-nitride epitaxial layer) on a more conductive polycrystalline silicon carbide substrate. The polycrystalline silicon carbide substrate may have, in some cases, one or more orders of magnitude lower resistivity relative to monocrystalline silicon carbide substrates.

In some embodiments, a method may include providing a wide bandgap epitaxial layer on a first substrate, such as a sapphire substrate. For instance, the wide bandgap epitaxial layer may be epitaxially formed on the first substrate. In some embodiments, a buffer layer may be between the first substrate and the wide bandgap epitaxial layer. The wide bandgap epitaxial layer may be an epitaxial silicon carbide layer or an epitaxial Group III-nitride layer. The buffer layer may be, for instance, an aluminum nitride layer or other suitable layer.

The method may include providing a surface of the wide bandgap epitaxial layer on a second substrate. For instance, the wide bandgap epitaxial layer may be “flipped” and placed on a polycrystalline silicon carbide substrate. The wide bandgap epitaxial layer may be attached (e.g., bonded, such as plasma bonded) to the polycrystalline silicon carbide substrate.

The method may include separating the first substrate (e.g., the sapphire substrate) from the wide bandgap epitaxial layer such that at least a portion of the wide bandgap epitaxial layer remains on the substrate. One example separation process may include inducing a cleavage plane in the wide bandgap epitaxial layer and separating the first substrate from the wide bandgap epitaxial layer along the cleavage plane. Inducing the cleavage plan may include emitting one or more lasers into the wide bandgap epitaxial layer.

Example techniques for inducing a cleavage plane using one or more lasers are disclosed in U.S. Pat. Nos. 10,576,585, 10,562,120, which are incorporated herein by reference. Other suitable techniques may be used to induce the cleavage plane without deviating from the scope of the present disclosure, such as implanting one or more species into the wide bandgap epitaxial layer.

In this way, a semiconductor wafer may be fabricated that includes a wide bandgap epitaxial layer on a polycrystalline silicon carbide substrate. Power semiconductor devices may be fabricated from the semiconductor wafer. The power semiconductor devices may have a polycrystalline silicon carbide substrate.

In some embodiments, a method may include providing a monocrystalline silicon carbide substrate layer and providing a polycrystalline silicon carbide substrate. The monocrystalline silicon carbide substrate layer may be attached (e.g., bonded) to the polycrystalline silicon carbide substrate. The monocrystalline silicon carbide substrate layer may be a portion of a boule of bulk monocrystalline silicon carbide, such as a boule of bulk 4H monocrystalline silicon carbide. The method may include separating a portion of the monocrystalline silicon carbide substrate layer such that a thin layer of monocrystalline silicon carbide remains on the polycrystalline silicon carbide layer. The method includes providing a wide bandgap epitaxial layer on the thin monocrystalline silicon carbide substrate layer remaining on the polycrystalline silicon carbide substrate. For instance, the wide bandgap epitaxial layer may be epitaxially formed on the monocrystalline silicon carbide substrate layer.

The polycrystalline silicon carbide substrate may be thicker than the monocrystalline silicon carbide substrate layer. In some examples, the monocrystalline silicon carbide substrate layer has a thickness in a range of about 1 μm to about 100 μm, such as about 1 μm to about 20 μm. The polycrystalline silicon carbide substrate layer may have a thickness in a range of about 50 μm to about 1000 μm or greater.

In some examples, providing the monocrystalline silicon carbide substrate layer on the polycrystalline silicon carbide layer may include attaching (e.g., bonding) a thick monocrystalline silicon carbide substrate (e.g., a boule or a portion of a boule) on the polycrystalline silicon carbide substrate. The method may include separating a portion of the thick monocrystalline silicon carbide substrate layer from the remainder of the monocrystalline silicon carbide substrate layer such that a thin portion of the monocrystalline silicon carbide substrate remains on the polycrystalline silicon carbide substrate.

One example separation process may include inducing a cleavage plane in the thick monocrystalline silicon carbide substrate layer and separating a portion of the thick monocrystalline silicon carbide substrate layer from the remainder of the monocrystalline silicon carbide substrate layer along the cleavage plane. Inducing the cleavage plan may include emitting one or more lasers into the monocrystalline silicon carbide substrate layer and/or implanting ions or species into the monocrystalline silicon carbide substrate layer.

Once a portion of the thick monocrystalline silicon carbide substrate layer has been removed or separated from the remaining portion of the monocrystalline silicon carbide substrate layer on the polycrystalline silicon carbide substrate, the portion of the thick monocrystalline silicon carbide substrate layer not attached to the polycrystalline silicon carbide substrate may be reused for different wide bandgap semiconductor wafers. For instance, the process may be repeated by attaching the left over portion of the thick monocrystalline silicon carbide substrate layer to a new polycrystalline silicon carbide substrate and performing another separation process to leave a new thin monocrystalline silicon carbide substrate layer on the new polycrystalline silicon carbide substrate.

In some examples, providing the monocrystalline silicon carbide substrate layer on the polycrystalline silicon carbide layer may include providing a thick monocrystalline silicon carbide substrate layer on a first substrate, such as a sapphire substrate to provide a first substrate assembly. For instance, the monocrystalline silicon carbide substrate layer may be attached (e.g., bonded) to the first substrate. In some embodiments, a buffer layer may be between the first substrate and the monocrystalline silicon carbide substrate layer. The buffer layer may be, for instance, an aluminum nitride layer or other suitable layer.

In some examples, the method may include separating a portion of the thick monocrystalline silicon carbide substrate layer from the first substrate assembly (e.g., a wafer). This will form a first substrate assembly including a thin monocrystalline silicon carbide substrate layer on the first substrate. One example separation process may include inducing a cleavage plane in the monocrystalline silicon carbide substrate layer and separating a portion of the monocrystalline silicon carbide substrate layer from the first substrate assembly. Inducing the cleavage plan may include emitting one or more lasers into the monocrystalline silicon carbide substrate layer. Other suitable techniques may be used to induce the cleavage plane without deviating from the scope of the present disclosure, such as implanting one or more species into the monocrystalline silicon carbide substrate layer.

The method may include providing the thin monocrystalline silicon carbide substrate layer on the polycrystalline silicon carbide substrate. For instance, the first substrate assembly with the thin monocrystalline silicon carbide substrate layer may be “flipped” and placed on a polycrystalline silicon carbide substrate. In some examples, the monocrystalline silicon carbide substrate may be bonded (e.g., plasma bonded) to the polycrystalline silicon carbide substrate.

The method may include separating the first substrate assembly from the polycrystalline silicon carbide substrate such that at least a portion of the monocrystalline silicon carbide substrate layer remains on the polycrystalline silicon carbide substrate. One example separation process may include inducing a cleavage plane in the monocrystalline silicon carbide substrate layer. Inducing the cleavage plan may include emitting one or more lasers into the monocrystalline silicon carbide substrate layer. Other suitable techniques may be used to induce the cleavage plane without deviating from the scope of the present disclosure, such as implanting one or more species into the monocrystalline silicon carbide substrate layer.

The method may include providing a wide bandgap epitaxial layer (e.g., epitaxial silicon carbide layer or epitaxial Group III-nitride layer) on the thin monocrystalline silicon carbide substrate layer. For instance, the wide bandgap epitaxial layer may be epitaxially formed on the first substrate. In this way, a semiconductor wafer may be fabricated that includes a wide bandgap epitaxial layer on a polycrystalline silicon carbide substrate with a thin layer of monocrystalline silicon carbide between the polycrystalline silicon carbide substrate and the wide band gap epitaxial layer. Power semiconductor devices may be fabricated from the semiconductor wafer.

Aspects of the present disclosure provide a number of technical effects and benefits. For instance, aspects of the present disclosure provide for fabrication of semiconductor device structures that eliminate or reduce the use of thick monocrystalline silicon carbide substrates and instead use more conductive polycrystalline silicon carbide substrates. Wide bandgap epitaxial layers may be provided on the polycrystalline silicon carbide substrates. This may allow for fabrication of power semiconductor devices with lower effective substrate resistance, enhancing performance of the power semiconductor devices while preserving the thickness of the substrate. This may result in lower reachable on-state resistance for the power semiconductor devices while preserving or even reducing breakage risks during wafer handling of the fabrication process.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

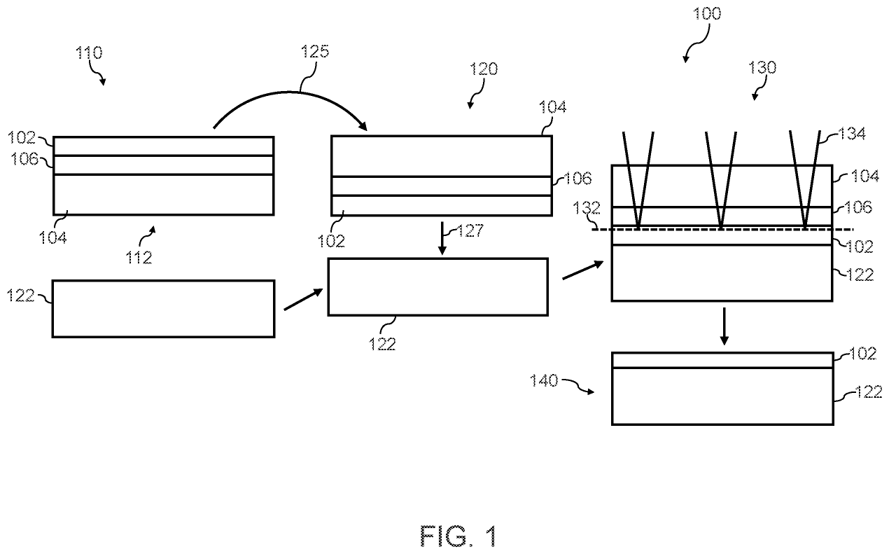

FIG. 1 depicts an overview of an example method 100 according to example embodiments of the present disclosure. FIG. 1 is intended to represent structures for identification and description and is not intended to represent the structures to physical scale. The method 100 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 110, the method may include providing a wide bandgap epitaxial layer 102 on a first substrate 104. The first substrate 104 may be a sapphire substrate, in some examples. Other suitable substrates (e.g., silicon carbide substrate such as a 4H silicon carbide substrate) may be used as the first substrate 104 without deviating from the scope of the present disclosure. The first substrate 104 may be in the form of a semiconductor wafer.

The wide bandgap epitaxial layer 102 may be formed by epitaxial growth. The wide bandgap epitaxial layer 102 may be, in some embodiments, a silicon carbide epitaxial layer. The wide bandgap epitaxial layer 102 may be, in some embodiments, a Group III-nitride. The wide bandgap epitaxial layer 102 may be formed using any suitable epitaxial growth process, such as hybrid vapor phase epitaxy (HVPE), metal-organic vapor phase epitaxy (MOVPE), molecular beam epitaxy (MBE), or other suitable growth process.

In some examples, the first substrate 104 may include a buffer layer 106. The buffer layer may be an epitaxial layer. The buffer layer 106 may be formed by epitaxial growth on the first substrate 104. The buffer layer 106 may be used to mitigate a lattice mismatch between, for instance, the first substrate 104 (e.g., sapphire substrate) and the wide bandgap epitaxial layer 102. In some embodiments, the buffer layer 106 may be a Group III-nitride, such as aluminum nitride.

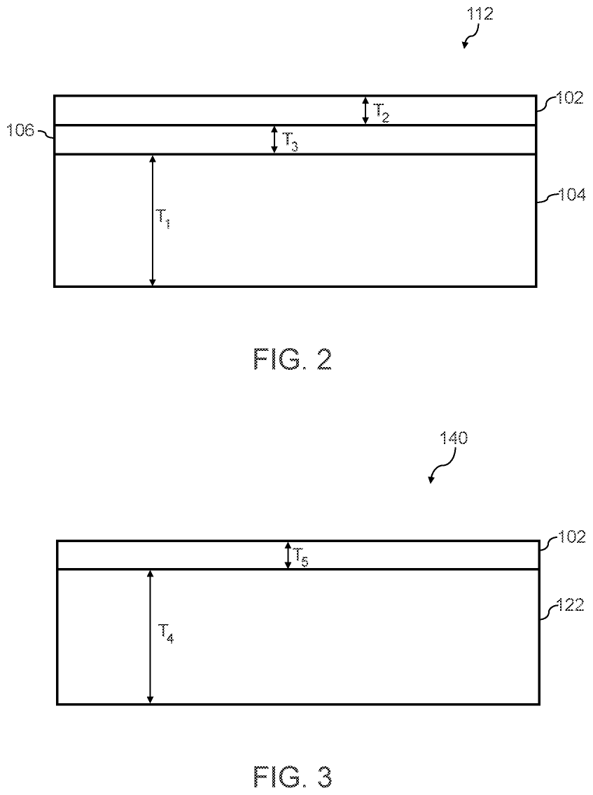

FIG. 2 depicts a cross-sectional view of an example semiconductor wafer 112 that may be formed, for instance, at 110 of the method 100 of FIG. 1. FIG. 2 is intended to represent structures for identification and description and is not intended to represent the structures to physical scale. As shown, the semiconductor wafer 112 includes a substrate 104 (e.g., sapphire substrate). The semiconductor wafer 112 includes a wide bandgap epitaxial layer 102 on the substrate 104. The wide bandgap epitaxial layer 102 may be, for instance, silicon carbide or a Group III-nitride.

The semiconductor wafer 112 shown in FIG. 2 includes a buffer layer 106. The buffer layer 106 may be between the substrate 104 (e.g., sapphire substrate) and the wide bandgap epitaxial layer 102. The buffer layer 106 may provide a crystal transition (e.g., by reducing a crystal lattice mismatch) between the substrate 104 (e.g., sapphire substrate) and the wide bandgap epitaxial layer 102. In some examples, the buffer layer 106 may be aluminum nitride. The buffer layer 106 may be an epitaxial layer.

In some examples, the substrate 104 (e.g., sapphire substrate) may have a thickness T1 in a range of, for instance, about 1 μm to about 1000 μm or greater, such as about 100 μm to about 1000 μm, such as about 150 μm to about 500 μm, such as about 180 μm to about 250 μm. The wide bandgap epitaxial layer 102 has a thickness T2 in a range of about 0.2 μm to about 200 μm, such as about 0.5 μm to about 100 μm, such as about 0.5 μm to about 20 μm. The buffer layer 106 may have a thickness T3 in a range of about 50 nm to about 10 μm, such as about 0.1 μm to about 5 μm.

Referring back to FIG. 1, the method may include at 120 providing a surface of the wide bandgap epitaxial layer 102 on a second substrate 122. The second substrate 122 may be a polycrystalline silicon carbide substrate (e.g., n-type polycrystalline silicon carbide substrate). For instance, the semiconductor wafer 112 (of FIG. 2) may be “flipped” at 125 and placed on a polycrystalline silicon carbide substrate 122 such that the wide bandgap epitaxial layer 102 is on the polycrystalline silicon carbide substrate 122.

The polycrystalline silicon carbide substrate 122 may be, for instance, a highly doped n-type polycrystalline silicon carbide substrate 122. The polycrystalline silicon carbide substrate 122 may be doped in other ways (e.g., doped p-type, etc.) without deviating from the scope of the present disclosure. In some embodiments, the polycrystalline silicon carbide substrate 122 may be only unintentionally doped or undoped (e.g., an unintentionally doped polycrystalline silicon carbide substrate).

Aspects of the present disclosure are discussed with reference to the substrate 122 being a polycrystalline silicon carbide substrate. Those of ordinary skill in the art, using the disclosures provided herein, will understand that the substrate may be other materials with thermal conductivity greater than a thermal conductivity associated with monocrystalline silicon carbide. For instance, the substrate 122 may be a Group III-nitride (e.g., aluminum nitride, gallium nitride, aluminum gallium nitride, etc.), silicon nitride, a ceramic substrate, etc.

The polycrystalline silicon carbide substrate 122 may be in the form of a semiconductor wafer. The polycrystalline silicon carbide substrate 122 may be formed, for instance, from epitaxial growth from a polycrystalline seed material. The polycrystalline silicon carbide substrate 122 may be separated from a boule.

The wide bandgap epitaxial layer 102 may be attached (e.g., plasma bonded) using a bonding process 127 to the polycrystalline silicon carbide substrate 122. The bonding process 127 may be a direct bonding or fusion bonding process where the wide bandgap epitaxial layer 102 is directly bonded to the polycrystalline silicon carbide substrate 122 with no intervening structures or layers between the polycrystalline silicon carbide substrate 122 and the wide bandgap epitaxial layer 102. The direct bonding process may be based, for instance, on van der Waals forces, covalent bonds, or other bonding between the polycrystalline silicon carbide substrate 122 and the wide bandgap epitaxial layer 102. A plasma pretreatment process or other pretreatment process may be performed on the surface(s) of the polycrystalline silicon carbide substrate 122 and/or the wide bandgap epitaxial layer 102 to prepare for the direct bonding of the wide bandgap epitaxial layer 102 to the polycrystalline silicon carbide substrate 122.

Referring to FIG. 1 at 130, the method 100 may include separating the first substrate 104 (e.g., the sapphire substrate) from the wide bandgap epitaxial layer 102 such that at least a portion of the wide bandgap epitaxial layer 102 remains on the second substrate 122 (the polycrystalline silicon carbide substrate). One example separation process may include inducing a cleavage plane 132 in the wide bandgap epitaxial layer 102 and separating the first substrate 104 from the wide bandgap epitaxial layer 102 along the cleavage plane 132. Inducing the cleavage plane 132 may include emitting one or more lasers 134 into the wide bandgap epitaxial layer 102 to induce damaged regions along the cleavage plane 132. Other suitable techniques may be used to induce the cleavage plane 132 without deviating from the scope of the present disclosure, such as implanting one or more species into the wide bandgap epitaxial layer 102.

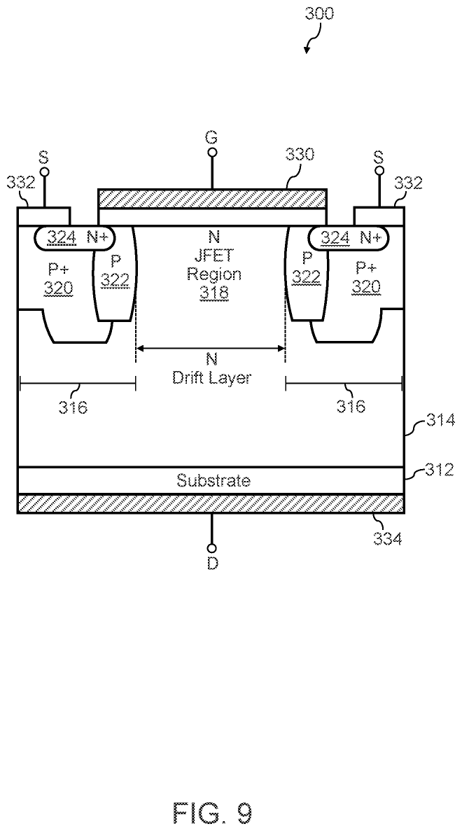

Once the first substrate 104 has been separated from the wide bandgap epitaxial layer 102, the method 100 yields a semiconductor wafer 140 with the wide bandgap epitaxial layer 102 directly on the second substrate 122 (e.g., the polycrystalline silicon carbide substrate). Power semiconductor devices may be fabricated from the semiconductor wafer 140. The power semiconductor devices may have a polycrystalline silicon carbide substrate. Example semiconductor devices that may be fabricated from the semiconductor wafer 140 are discussed with reference to FIGS. 9-12.

In some examples, after separating the first substrate 104 from the wide bandgap epitaxial layer 102 such that as least a portion of the wide bandgap epitaxial layer 102 remains on the second substrate 122, there still may be sufficient remaining thickness of the wide bandgap epitaxial layer 102 on the first substrate 104. In these examples, the remaining wide bandgap epitaxial layer 102 may be bonded to another polycrystalline silicon carbide substrate 122 and another separation process performed to provide another semiconductor wafer 140 with the wide bandgap epitaxial layer on a second substrate 122. This process may be repeated as many times as possible until there is no longer sufficient remaining wide bandgap epitaxial layer 102 on the first substrate 122.

FIG. 3 depicts a cross-sectional view of an example semiconductor wafer 140 according to example embodiments of the present disclosure. FIG. 3 is intended to represent structures for identification and description and is not intended to represent the structures to physical scale. The semiconductor wafer 140 includes a polycrystalline silicon carbide substrate 122 and a wide bandgap epitaxial layer 102 on the polycrystalline silicon carbide substrate 122. The wide bandgap epitaxial layer 102 may be directly on the polycrystalline silicon carbide substrate 122 such that there are no intervening structures between the wide bandgap epitaxial layer 102 and the polycrystalline silicon carbide substrate 122.

The wide bandgap epitaxial layer 102 may be a silicon carbide epitaxial layer or a Group III-nitride epitaxial layer (e.g., a gallium nitride epitaxial layer). The polycrystalline silicon carbide substrate 122 may be, for instance, a highly doped N+ type polycrystalline silicon carbide substrate 122. The polycrystalline silicon carbide substrate 122 may be doped in other ways (e.g., doped P type, etc.) without deviating from the scope of the present disclosure. In some embodiments, the polycrystalline silicon carbide substrate 122 may be only unintentionally doped or undoped.

The wide bandgap epitaxial layer 102 may be bonded (e.g., directly bonded) to the polycrystalline silicon carbide substrate 122 (e.g., using van der Waals forces or other suitable bonding). The wide bandgap epitaxial layer 102 may be plasma bonded to the polycrystalline silicon carbide substrate 122. For instance, one or more surfaces of the polycrystalline silicon carbide substrate 122 and/or the wide bandgap epitaxial layer 102 may be plasma-treated during bonding.

The polycrystalline silicon carbide substrate 122 may have a thickness T4, for instance, in a range of about 1 μm to about 1000 μm or greater, such as about 100 μm to about 1000 μm, such as about 150 μm to about 500 μm, such as about 180 μm to about 250 μm. The wide bandgap epitaxial layer 102 has a thickness T5 in a range of about 0.2 μm to about 200 μm, such as about 0.5 μm to about 100 μm, such as about 0.5 μm to about 20 μm. The polycrystalline silicon carbide substrate 122 and/or the semiconductor wafer 140 may have a diameter of about 150 mm or greater, such as about 200 mm or greater, such as in a range of about 150 mm to about 300 mm.

In some examples, the semiconductor wafer 140 may be subjected to a fabrication process to form one or more semiconductor devices, such as one or more transistors or diodes. In some examples, the semiconductor devices may be, for instance, one or more MOSFETs, IGBTs, HEMTs, or Schottky diodes. Example semiconductor devices that may be fabricated from semiconductor wafer 140 are depicted in FIGS. 9-12.

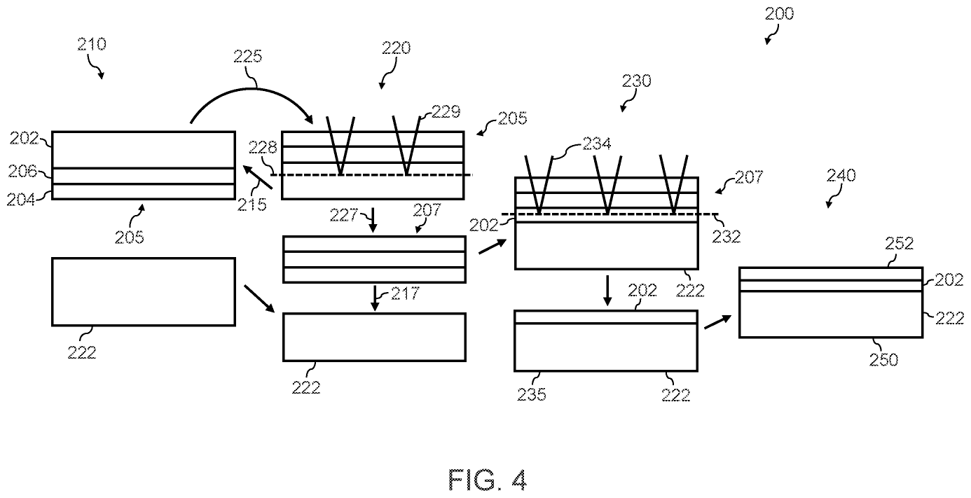

FIG. 4 depicts an overview of an example method 200 according to example embodiments of the present disclosure. FIG. 4 is intended to represent structures for identification and description and is not intended to represent the structures to physical scale. The method 200 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 210, the method may include providing a monocrystalline silicon carbide substrate layer 202 on a first substrate 204. This forms a first substrate assembly 205. The first substrate 204 may be a sapphire substrate, in some examples. Other suitable substrates may be used as the first substrate 204 without deviating from the scope of the present disclosure. The first substrate 204 may be in the form of a semiconductor wafer. The monocrystalline silicon carbide substrate layer 202 may be, for instance, a 4H monocrystalline silicon carbide substrate layer and may, for instance, be in the form of a boule or a portion of a boule or other bulk substrate.

In some examples, the first substrate 204 may include a buffer layer 206. The buffer layer may be an epitaxial layer. The buffer layer 206 may be formed by epitaxial growth on the first substrate 204. The buffer layer 206 may be used to mitigate a lattice mismatch between, for instance, the first substrate 204 (e.g., sapphire substrate) and the monocrystalline silicon carbide substrate layer 202. In some embodiments, the buffer layer 206 may be a Group III-nitride, such as aluminum nitride.

In some examples, the monocrystalline silicon carbide substrate layer 202 may be provided on the first substrate 204 by attaching (e.g., bonding) the monocrystalline silicon carbide substrate layer 202 to the first substrate 204 using, for instance, a bonding process. The bonding process may be a direct bonding or fusion bonding process where the monocrystalline silicon carbide substrate layer 202 is directly bonded to the first substrate 204 (e.g., the buffer layer 206). The direct bonding process may be based, for instance, on van der Waals forces, covalent bonds, or other bonding between the monocrystalline silicon carbide substrate layer 202 and the first substrate 204 (e.g., the buffer layer 206). A plasma pretreatment process or other pretreatment process may be performed on the surface(s) to prepare for the direct bonding of the monocrystalline silicon carbide substrate layer 202 to the first substrate 204 (e.g., buffer layer 206).

In some examples, the monocrystalline silicon carbide substrate layer 202 may be provided on the first substrate 204 by epitaxial growth. The monocrystalline silicon carbide substrate layer 202 may be formed using any suitable epitaxial growth process, such as hybrid vapor phase epitaxy (HVPE), metal-organic vapor phase epitaxy (MOVPE), molecular beam epitaxy (MBE), or other suitable growth process.

At 220, the method may include separating a portion of the monocrystalline silicon carbide substrate layer 202 with the first substrate 204 (e.g., a portion of the first substrate assembly 205) from the bulk remainder of the monocrystalline silicon carbide substrate layer 202. This will form a substrate assembly 207 with a thinner monocrystalline silicon carbide substrate layer 202 (e.g., thickness in a range of about 1 μm to about 100 μm, such as about 1 μm to about 20 μm) on the first substrate 204. One example separation process may include inducing a cleavage plane 228 in the monocrystalline silicon carbide substrate layer 202 and separating a portion of the monocrystalline silicon carbide substrate layer 202 with the first substrate 204 from the bulk remainder of the monocrystalline silicon carbide substrate layer 202. Inducing the cleavage plan 228 may include emitting one or more lasers 229 into the monocrystalline silicon carbide substrate layer 202 to induce damaged regions along the cleavage plane 228. Other suitable techniques may be used to induce the cleavage plane 228 without deviating from the scope of the present disclosure, such as implanting one or more species into the monocrystalline silicon carbide substrate layer 202.

In some examples, the remaining bulk of the monocrystalline silicon carbide substrate layer 202 that has been separated from the first substrate 204 may be reused in subsequent processes by attaching the remaining bulk of the monocrystalline silicon carbide substrate layer 202 to another first substrate 204 (e.g., a sapphire substrate) and/or to a different polycrystalline silicon carbide substrate. The operations of the method 200 may then be repeated for the remaining bulk of the monocrystalline silicon carbide substrate layer 202 on the new first substrate 204 (e.g., sapphire substrate).

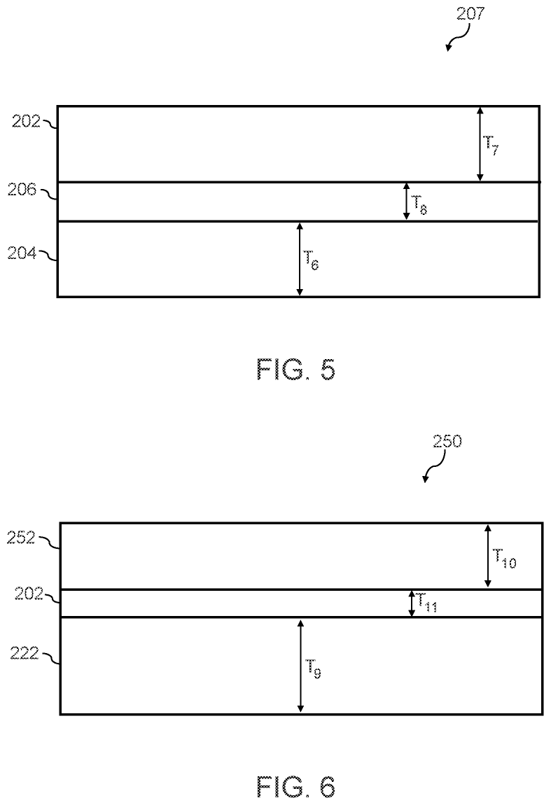

FIG. 5 depicts a cross-sectional view of an example semiconductor wafer 207 that may be formed, for instance, at 220 of the method 200 of FIG. 4. FIG. 5 is intended to represent structures for identification and description and is not intended to represent the structures to physical scale. As shown, the semiconductor wafer 212 includes a substrate 204 (e.g., sapphire substrate). The semiconductor wafer 212 includes a monocrystalline silicon carbide substrate layer 202 on the substrate 204. The monocrystalline silicon carbide substrate layer 202 may be, for instance, a 4H silicon carbide layer.

The semiconductor wafer 212 shown in FIG. 5 includes a buffer layer 206. The buffer layer 206 may be between the substrate 204 (e.g., sapphire substrate) and the monocrystalline silicon carbide substrate layer 202. The buffer layer 206 may provide a crystal transition (e.g., by reducing a crystal lattice mismatch) between the substrate 204 (e.g., sapphire substrate) and the monocrystalline silicon carbide substrate layer 202. In some examples, the buffer layer 206 may be aluminum nitride. The buffer layer 206 may be an epitaxial layer.

In some examples, the substrate 204 (e.g., sapphire substrate) may have a thickness T6 in a range of, for instance, about 1 μm to about 1000 μm or greater, such as about 100 μm to about 1000 μm, such as about 150 μm to about 500 μm, such as about 180 μm to about 250 μm. The monocrystalline silicon carbide substrate layer 202 has a thickness T7 in a range of about 0.2 μm to about 200 μm, such as about 0.5 μm to about 100 μm, such as about 0.5 μm to about 20 μm. The buffer layer 206 may have a thickness T8 in a range of about 50 nm to about 10 μm, such as about, 0.1 μm to about 5 μm.

Referring back to FIG. 4 at 220, the method may include providing a surface of the monocrystalline silicon carbide substrate layer 202 on a second substrate 222. The second substrate 222 may be a polycrystalline silicon carbide substrate or other material with sufficient thermal conductivity, such as a Group III-nitride (e.g., aluminum nitride, gallium nitride, aluminum gallium nitride, etc.), silicon nitride, a ceramic substrate, or the like. For instance, the semiconductor wafer 212 (of FIG. 5) may be “flipped” at 225 and placed on a polycrystalline silicon carbide substrate 222 such that the monocrystalline silicon carbide substrate layer 202 is on the polycrystalline silicon carbide substrate 222.

The polycrystalline silicon carbide substrate 222 may be, for instance, a highly doped n-type polycrystalline silicon carbide substrate 222. The polycrystalline silicon carbide substrate 222 may be doped in other ways (e.g., doped p-type, etc.) without deviating from the scope of the present disclosure. In some embodiments, the polycrystalline silicon carbide substrate 222 may be only unintentionally doped or undoped (e.g., an unintentionally doped polycrystalline silicon carbide substrate).

Aspects of the present disclosure are discussed with reference to the substrate 222 being a polycrystalline silicon carbide substrate. Those of ordinary skill in the art, using the disclosures provided herein, will understand that the substrate may be other materials with thermal conductivity greater than a thermal conductivity associated with monocrystalline silicon carbide. For instance, the substrate 222 may be a Group III-nitride (e.g., aluminum nitride, gallium nitride, aluminum gallium nitride, etc.), silicon nitride, a ceramic substrate, etc.

The polycrystalline silicon carbide substrate 222 may be in the form of a semiconductor wafer. The polycrystalline silicon carbide substrate 222 may be formed, for instance, from epitaxial growth from a polycrystalline seed material. The polycrystalline silicon carbide substrate 222 may be separated from a boule.

The monocrystalline silicon carbide substrate layer 202 of the assembly 207 may be attached (e.g., plasma bonded) using a bonding process 227 to the polycrystalline silicon carbide substrate 222. The bonding process 227 may be a direct bonding or fusion bonding process where the monocrystalline silicon carbide substrate layer 202 is directly bonded to the polycrystalline silicon carbide substrate 222 with no intervening structures or layers between the polycrystalline silicon carbide substrate 222 and the monocrystalline silicon carbide substrate layer 202. The direct bonding process may be based, for instance, on van der Waals forces, covalent bonds, or other bonding between the polycrystalline silicon carbide substrate 222 and the monocrystalline silicon carbide substrate layer 202. A plasma pretreatment process or other pretreatment process may be performed on the surface(s) of the polycrystalline silicon carbide substrate 222 and/or the monocrystalline silicon carbide substrate layer 202 to prepare for the direct bonding of the wide bandgap epitaxial layer 202 to the polycrystalline silicon carbide substrate 222.

Referring to FIG. 4 at 230, the method 200 may include separating the first substrate 204 (e.g., the sapphire substrate) from the monocrystalline silicon carbide substrate layer 202 such that at least a portion of the monocrystalline silicon carbide substrate layer 202 remains on the second substrate 222 (e.g., the polycrystalline silicon carbide substrate). In some examples, separating the first substrate from the monocrystalline silicon carbide substrate layer occurs after providing the monocrystalline silicon carbide substrate layer on the second substrate. One example separation process may include inducing a cleavage plane 232 in the monocrystalline silicon carbide substrate layer 202 and separating the first substrate 204 from the monocrystalline silicon carbide substrate layer 202 along the cleavage plane 232. Inducing the cleavage plane 232 may include emitting one or more lasers 234 into the wide monocrystalline silicon carbide substrate layer 202 to induce damaged regions along the cleavage plane 232. Other suitable techniques may be used to induce the cleavage plane 232 without deviating from the scope of the present disclosure, such as implanting one or more species into monocrystalline silicon carbide substrate layer 202. Once the first substrate 204 has been separated from the monocrystalline silicon carbide substrate layer 202, the method 200 yields a semiconductor wafer 235 including a monocrystalline silicon carbide substrate layer 202 (e.g., 4H monocrystalline silicon carbide) on the second substrate 222 (e.g., polycrystalline silicon carbide substrate).

Referring to FIG. 4 at 240, the method 200 may include providing a wide bandgap epitaxial layer 252 on the monocrystalline silicon carbide substrate layer 202. The wide bandgap epitaxial layer 252 may be formed by epitaxial growth. The wide bandgap epitaxial layer 252 may be, in some embodiments, a silicon carbide epitaxial layer. The wide bandgap epitaxial layer 252 may be, in some embodiments, a Group III-nitride. The wide bandgap epitaxial layer 252 may be formed using any suitable epitaxial growth process, such as hybrid vapor phase epitaxy (HVPE), metal-organic vapor phase epitaxy (MOVPE), molecular beam epitaxy (MBE), or other suitable growth process.

In this way, the method 200 yields a semiconductor wafer 250 with the wide bandgap epitaxial layer 252 directly on a monocrystalline silicon carbide substrate layer 202, which is directly on a polycrystalline silicon carbide substrate 222. Power semiconductor devices may be fabricated from the semiconductor wafer 250. The power semiconductor devices may have a substrate that includes a monocrystalline silicon carbide substrate layer 202 on a polycrystalline silicon carbide substrate 222. Example semiconductor devices that may be fabricated from the semiconductor wafer 250 are discussed with reference to FIGS. 9-12.

FIG. 6 depicts a cross-sectional view of an example semiconductor wafer 250 according to example embodiments of the present disclosure. FIG. 6 is intended to represent structures for identification and description and is not intended to represent the structures to physical scale. The semiconductor wafer 250 includes a polycrystalline silicon carbide substrate 222 and a wide bandgap epitaxial layer 252 on the polycrystalline silicon carbide substrate 222. A monocrystalline silicon carbide substrate layer 202 (e.g., 4H monocrystalline silicon carbide substrate layer) is between the polycrystalline silicon carbide substrate 222 and the wide bandgap epitaxial layer 252. The wide bandgap epitaxial layer 252 may be directly on the monocrystalline silicon carbide substrate layer 202 such that there are no intervening structures between the wide bandgap epitaxial layer 252 and the monocrystalline silicon carbide substrate layer 202. The monocrystalline silicon carbide substrate layer 202 may be directly on the polycrystalline silicon carbide substrate 222 such that there are no intervening structures between the monocrystalline silicon carbide substrate layer 202 and the polycrystalline silicon carbide substrate 222.

The wide bandgap epitaxial layer 252 may be a silicon carbide epitaxial layer or a Group III-nitride epitaxial layer (e.g., a gallium nitride epitaxial layer). The polycrystalline silicon carbide substrate 222 may be, for instance, a highly doped N+ type polycrystalline silicon carbide substrate. The polycrystalline silicon carbide substrate 222 may be doped in other ways (e.g., doped P type, etc.) without deviating from the scope of the present disclosure. In some embodiments, the polycrystalline silicon carbide substrate 222 may be only unintentionally doped or undoped.

The monocrystalline silicon carbide substrate layer 202 may be attached (e.g., directly bonded) to the polycrystalline silicon carbide substrate 222 (e.g., using van der Waals forces or other suitable bonding). The monocrystalline silicon carbide substrate layer 202 may be plasma bonded to the polycrystalline silicon carbide substrate 222. For instance, one or more surfaces of the polycrystalline silicon carbide substrate 222 and/or the monocrystalline silicon carbide substrate layer 202 may be plasma-treated during bonding.

The polycrystalline silicon carbide substrate 222 may have a thickness T9, for instance, in a range of about 1 μm to about 1000 μm or greater, such as about 100 μm to about 1000 μm, such as about 150 μm to about 500 μm, such as about 180 μm to about 250 μm. The wide bandgap epitaxial layer 252 has a thickness T10 in a range of about 0.2 μm to about 200 μm, such as about 0.5 μm to about 100 μm, such as about 0.5 μm to about 10 μm. The monocrystalline silicon carbide substrate layer 202 may have a thickness T11 in a range of about 0.2 μm to about 200 μm, such as about 0.5 μm to about 100 μm, such as about 0.5 μm to about 20 μm. The polycrystalline silicon carbide substrate 222 and/or the semiconductor wafer 250 may have a diameter of about 150 mm or greater, such as about 200 mm or greater, such as in a range of about 150 mm to about 300 mm.

In some examples, the semiconductor wafer 250 may be subjected to a fabrication process to form one or more semiconductor devices, such as one or more transistors or diodes. In some examples, the semiconductor devices may be, for instance, one or more MOSFETs, IGBTs, HEMTs, or Schottky diodes. Example semiconductor devices that may be fabricated from semiconductor wafer 250 are depicted in FIGS. 9-12.

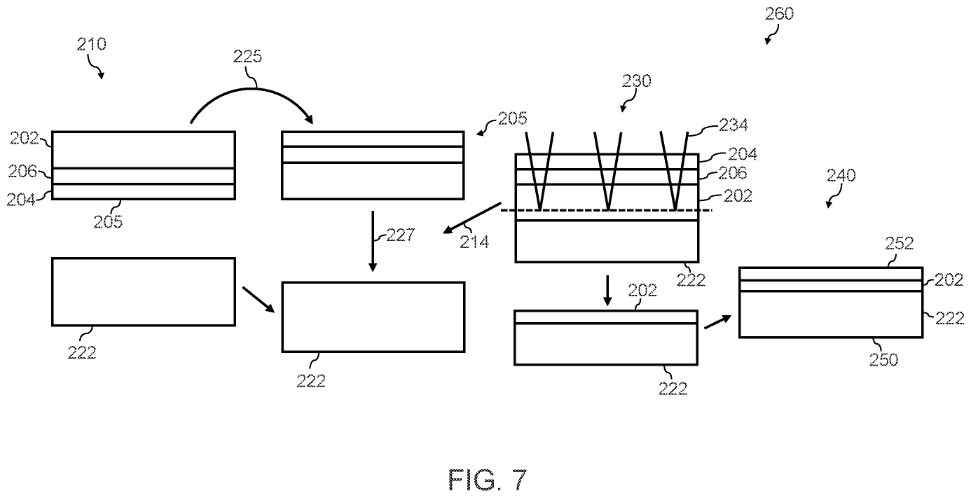

FIG. 7 depicts an overview of an example method 260 according to example embodiments of the present disclosure. FIG. 7 is intended to represent structures for identification and description and is not intended to represent the structures to physical scale. The method 260 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

FIG. 7 is similar to the method 200 of FIG. 4. However, the method 260 does not include the separation operation 220 described with reference to FIG. 4. Rather, the method 260 attaches the entire first substrate assembly 205 formed at 210 to the polycrystalline substrate 222.

More particularly, the monocrystalline silicon carbide substrate layer 202 of the first substrate assembly 205 may be attached (e.g., plasma bonded) using a bonding process 227 to the polycrystalline silicon carbide substrate 222. The bonding process 227 may be a direct bonding or fusion bonding process where the monocrystalline silicon carbide substrate layer 202 is directly bonded to the polycrystalline silicon carbide substrate 222 with no intervening structures or layers between the polycrystalline silicon carbide substrate 222 and the monocrystalline silicon carbide substrate layer 202. The direct bonding process may be based, for instance, on van der Waals forces, covalent bonds, or other bonding between the polycrystalline silicon carbide substrate 222 and the monocrystalline silicon carbide substrate layer 202. A plasma pretreatment process or other pretreatment process may be performed on the surface(s) of the polycrystalline silicon carbide substrate 222 and/or the monocrystalline silicon carbide substrate layer 202 to prepare for the direct bonding of the monocrystalline silicon carbide substrate layer 202 to the polycrystalline silicon carbide substrate 222.

Referring to FIG. 7 at 230, the method 260 may include separating the first substrate assembly 205 from a portion the monocrystalline silicon carbide substrate layer 202 such that at least a portion of the monocrystalline silicon carbide substrate layer 202 remains on the second substrate 222 (e.g., the polycrystalline silicon carbide substrate). In some examples, the first substrate assembly 205 with the remaining monocrystalline silicon carbide substrate layer 202 that has been separated away may then be reused with a different polycrystalline silicon carbide substrate 222 as indicated at 214.

One example separation process may include inducing a cleavage plane 232 in the monocrystalline silicon carbide substrate layer 202 and separating the first substrate 204 from the monocrystalline silicon carbide substrate layer 202 along the cleavage plane 232. Inducing the cleavage plane 232 may include emitting one or more lasers 234 into the wide monocrystalline silicon carbide substrate layer 202 to induce damaged regions along the cleavage plane 232. Other suitable techniques may be used to induce the cleavage plane 232 without deviating from the scope of the present disclosure, such as implanting one or more species into monocrystalline silicon carbide substrate layer 202. Once the first substrate 204 has been separated from the monocrystalline silicon carbide substrate layer 202, the method 200 yields a semiconductor wafer 235 including a monocrystalline silicon carbide substrate layer 202 (e.g., 4H monocrystalline silicon carbide) on the second substrate (e.g., polycrystalline silicon carbide).

Referring to FIG. 7 at 240, the method 260 may include providing a wide bandgap epitaxial layer 252 on the monocrystalline silicon carbide substrate layer 202. The wide bandgap epitaxial layer 252 may be formed by epitaxial growth. The wide bandgap epitaxial layer 252 may be, in some embodiments, a silicon carbide epitaxial layer. The wide bandgap epitaxial layer 252 may be, in some embodiments, a Group III-nitride. The wide bandgap epitaxial layer 252 may be formed using any suitable epitaxial growth process, such as hybrid vapor phase epitaxy (HVPE), metal-organic vapor phase epitaxy (MOVPE), molecular beam epitaxy (MBE), or other suitable growth process.

In this way, the method 260 yields a semiconductor wafer 250 with the wide bandgap epitaxial layer 252 directly on a monocrystalline silicon carbide substrate layer 202, which is directly on a polycrystalline silicon carbide substrate. Power semiconductor devices may be fabricated from the semiconductor wafer 250. The power semiconductor devices may have a substrate that includes a monocrystalline silicon carbide substrate layer 202 on a polycrystalline silicon carbide substrate 222. Example semiconductor devices that may be fabricated from the semiconductor wafer 250 are discussed with reference to FIGS. 9-12.

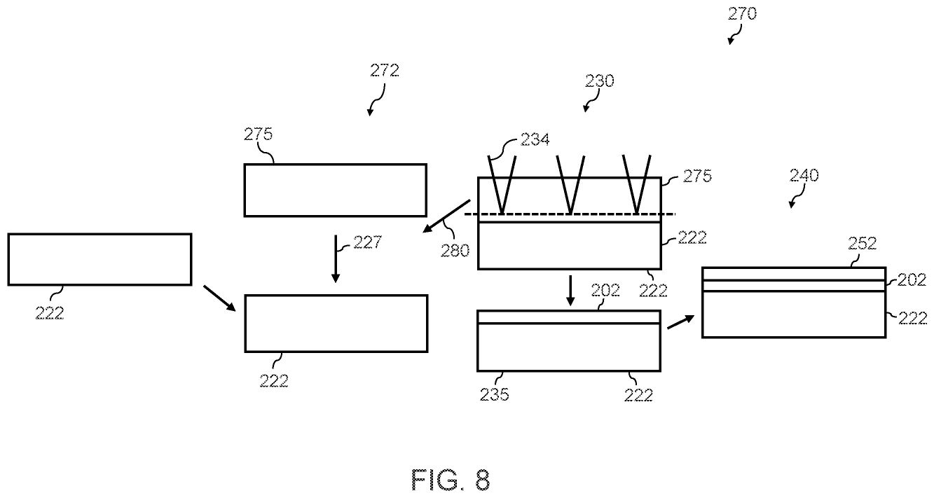

FIG. 8 depicts an overview of an example method 270 according to example embodiments of the present disclosure. FIG. 8 is intended to represent structures for identification and description and is not intended to represent the structures to physical scale. The method 270 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

FIG. 8 is similar to the method 200 of FIG. 4 and the method 260 of FIG. 7. However, the method 270 does not provide a monocrystalline silicon carbide substrate layer on a first substrate (to form an assembly such as a wafer) prior to attaching the monocrystalline silicon carbide layer to the polycrystalline silicon carbide substrate 222. Rather, the method 270 of FIG. 8 simply attaches the monocrystalline silicon carbide layer 275 (e.g., in the form of a boule or bulk substrate) to the polycrystalline silicon carbide substrate 222.

More particularly, the monocrystalline silicon carbide substrate layer 275 may be attached (e.g., plasma bonded) using a bonding process 227 to the polycrystalline silicon carbide substrate 222. The bonding process 227 may be a direct bonding or fusion bonding process where the monocrystalline silicon carbide substrate layer 275 is directly bonded to the polycrystalline silicon carbide substrate 222 with no intervening structures or layers between the polycrystalline silicon carbide substrate 222 and the monocrystalline silicon carbide substrate layer 275. The direct bonding process may be based, for instance, on van der Waals forces, covalent bonds, or other bonding between the polycrystalline silicon carbide substrate 222 and the monocrystalline silicon carbide substrate layer 275. A plasma pretreatment process or other pretreatment process may be performed on the surface(s) of the polycrystalline silicon carbide substrate 222 and/or the monocrystalline silicon carbide substrate layer 275 to prepare for the direct bonding of the monocrystalline silicon carbide substrate layer 275 to the polycrystalline silicon carbide substrate 222.

Referring to FIG. 8 at 230, the method 270 may include separating a portion the monocrystalline silicon carbide substrate layer 275 such at least a portion of the monocrystalline silicon carbide substrate layer 202 remains on the second substrate 222 (e.g., the polycrystalline silicon carbide substrate). In some examples, the remaining monocrystalline silicon carbide substrate layer that has been separated may then be reused with a different polycrystalline silicon carbide substrate 222 as indicated at 280.

One example separation process may include inducing a cleavage plane 232 in the monocrystalline silicon carbide substrate layer 275 and separating a portion of the monocrystalline silicon carbide substrate layer 275 along the cleavage plane 232. Inducing the cleavage plane 232 may include emitting one or more lasers 234 into the wide monocrystalline silicon carbide substrate layer 275 to induce damaged regions along the cleavage plane 232. Other suitable techniques may be used to induce the cleavage plane 232 without deviating from the scope of the present disclosure, such as implanting one or more species into monocrystalline silicon carbide substrate layer 275. Once the portion of the polycrystalline silicon substrate layer 275 has been separated from the monocrystalline silicon carbide substrate layer 202 remaining on the polycrystalline silicon carbide substrate 222, the method 200 yields a semiconductor wafer 235 including a monocrystalline silicon carbide substrate layer 202 (e.g., 4H monocrystalline silicon carbide) on the second substrate 222 (e.g., polycrystalline silicon carbide).

Referring to FIG. 8 at 240, the method 270 may include providing a wide bandgap epitaxial layer 252 on the monocrystalline silicon carbide substrate layer 202. The wide bandgap epitaxial layer 252 may be formed by epitaxial growth. The wide bandgap epitaxial layer 252 may be, in some embodiments, a silicon carbide epitaxial layer. The wide bandgap epitaxial layer 252 may be, in some embodiments, a Group III-nitride. The wide bandgap epitaxial layer 252 may be formed using any suitable epitaxial growth process, such as hybrid vapor phase epitaxy (HVPE), metal-organic vapor phase epitaxy (MOVPE), molecular beam epitaxy (MBE), or other suitable growth process.

In this way, the method 270 yields a semiconductor wafer 250 with the wide bandgap epitaxial layer 252 directly on a monocrystalline silicon carbide substrate layer 202, which is directly on a polycrystalline silicon carbide substrate 222. Power semiconductor devices may be fabricated from the semiconductor wafer 250. The power semiconductor devices may have a substrate that includes a monocrystalline silicon carbide substrate layer 202 on a polycrystalline silicon carbide substrate 222. Example semiconductor devices that may be fabricated from the semiconductor wafer 250 are discussed with reference to FIGS. 9-12.

FIG. 9 shows an example power semiconductor device that is a MOSFET 300. FIG. 9 is intended to represent structures for identification and description and is not intended to represent the structures to physical scale. The MOSFET 300 may be fabricated from a semiconductor wafer according to example embodiments of the present disclosure and includes a substrate including polycrystalline silicon carbide. The MOSFET 300 is an example vertical power semiconductor device having a first contact on a wide bandgap epitaxial layer and a second contact on a polycrystalline silicon carbide substrate.

The MOSFET includes a substrate 312 and a drift layer 314 formed over the substrate 312. In some examples, the substrate 312 may be a polycrystalline silicon carbide substrate. The drift layer 314 may be fabricated from a silicon carbide epitaxial layer on the polycrystalline silicon carbide substrate. The substrate 312 and drift layer 314 may be fabricated from a semiconductor wafer, such as semiconductor wafer 140 of FIG. 3. In some examples, the substrate 312 may include a polycrystalline silicon carbide substrate and a monocrystalline silicon carbide substrate layer (e.g., 4H monocrystalline silicon carbide substrate layer) on the polycrystalline silicon carbide substrate. The drift layer 314 may be fabricated from a silicon carbide epitaxial layer on the monocrystalline silicon carbide substrate layer. The substrate 312 and drift layer 314 may be fabricated from a semiconductor wafer, such as semiconductor wafer 250 of FIG. 6.

One or more junction implants 316 extend into the drift layer 314 from a top surface of the drift layer 314, wherein the top surface is opposite the substrate 312. A junction gate field effect transistor (JFET) region 318 is provided between the junction implants 316. Each one of the junction implants 316 is formed by an ion implantation process, and includes a deep well region 320, a base region 322, and a source region 324.

Each deep well region 320 extends from a corner of the drift layer 314 opposite the substrate 312 downwards towards the substrate 312 and inwards towards the center of the drift layer 314. The deep well region 320 may be formed uniformly or may include one or more protruding regions, as shown in FIG. 9. Each base region 322 extends downward from the top surface of the drift layer 314 towards the substrate 312 along a portion of the inner edge of each one of the deep well regions 320. Each source region 324 is formed in a shallow portion beneath the top surface of the drift layer 314 and generally overlaps a portion of the deep well region 320 and the base region 322, without extending outside of either. The JFET region 318 defines a channel width 326 between each one of the junction implants 316. In an example configuration, the drift layer 314 and JFET region 318 are moderately doped with an N-type doping material (N), the deep well regions 320 are heavily doped with a P-type doping material (P+), the base regions 322 are moderately doped with a P-type doping material (P), and the source regions 324 are heavily doped with an N-type doping material (N+).

A gate dielectric is formed along the top surface of the drift layer 314 and extends laterally between each source region 324, such that portions of the gate dielectric extend over the base regions 322 and at least a portion of the source regions. A gate contact 330 is formed over the gate dielectric. Source contacts 332 are formed on the top surface of the drift layer 314 and over the source regions 324, such that each one of the source contacts 332 partially overlaps portions of both the source region 324 and the deep well region 320 without contacting the gate dielectric 328 or the gate contact 330. A drain contact 334 is located on the bottom surface of the substrate 312 opposite the drift layer 314.

In operation, when a biasing voltage is not applied to the gate contact 330 and the drain contact 334 is positively biased, the P-N junction between each deep well region 320 and the drift layer 314 is reverse biased, thereby placing the conventional MOSFET 300 in an OFF state. In the OFF state of the MOSFET 300, any voltage between the source contacts 332 and drain contact 334 is supported by the drift layer 314 and only leakage currents will flow between these contacts. Due to the vertical structure of the MOSFET 300, large voltages may be placed between the source contacts 332 and the drain contact 334 without damaging the device.

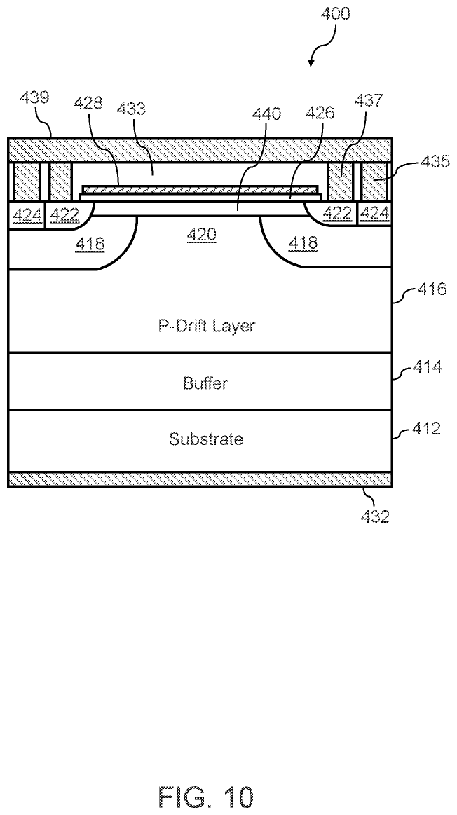

FIG. 10 shows an example power semiconductor device that is an IGBT 400. FIG. 10 is intended to represent structures for identification and description and is not intended to represent the structures to physical scale. The IGBT 400 may be fabricated from a semiconductor wafer according to example embodiments of the present disclosure and includes a substrate including polycrystalline silicon carbide. The IGBT 400 is an example vertical power semiconductor device having a first contact on a wide bandgap epitaxial layer and a second contact on a polycrystalline silicon carbide substrate.

The IGBT 400 of FIG. 10 includes a p-type buffer layer 414 and a p− drift epitaxial layer 416 on an n-type substrate 412. The substrate 412 may include an n+-type substrate. In some examples, the substrate 412 may be a polycrystalline silicon carbide substrate. The p-type buffer layer 414 and a p− drift epitaxial layer 416 may be fabricated from a silicon carbide epitaxial layer on the polycrystalline silicon carbide substrate. The substrate 412 and p-type buffer layer 414 and a p− drift epitaxial layer 416 may be fabricated from a semiconductor wafer, such as semiconductor wafer 140 of FIG. 3. In some examples, the substrate 412 may include a polycrystalline silicon carbide substrate and a monocrystalline silicon carbide substrate layer (e.g., 4H monocrystalline silicon carbide substrate layer) on the polycrystalline silicon carbide substrate. The p-type buffer layer 414 and a p− drift epitaxial layer 416 may be fabricated from a silicon carbide epitaxial layer on the monocrystalline silicon carbide substrate layer. The substrate 412 and p-type buffer layer 414 and a p− drift epitaxial layer 416 may be fabricated from a semiconductor wafer, such as semiconductor wafer 250 of FIG. 6.

The p− drift layer 416 may have a thickness of about 110 μm and may be doped with p-type dopants at a doping concentration selected to provide a desired blocking voltage. For example, the p− drift layer 416 may be doped with p-type dopants at a doping concentration of about 2×10¹⁴ cm⁻³ to about 6×10¹⁴ cm⁻³ for a 10 kV blocking capability. The p-type buffer layer 414 may have a thickness of about 1 μm to about 2 μm and may be doped with p-type dopants at a doping concentration of about 1×10¹⁷ cm-3. The p-type buffer layer 414 is provided as a channel stop layer to discourage punch-through.

N+ well regions 418 are formed at a surface of the p-type drift layer 416. The n+ well regions 418, which may be formed by ion implantation, may extend a distance of about 0.5 μm into the drift layer 416.

An epitaxial p-type channel adjustment layer 440 is on the drift layer 416. The channel adjustment layer 440 may have a thickness of about 0.1 μm to about 0.5 μm, and may be doped with p-type dopants to have a net acceptor concentration of about 1×10¹⁶ cm-3 to about 5×10¹⁸ cm-3. In particular, the epitaxial p-type channel adjustment layer 440 may have a thickness of about 0.25 μm and may be doped with acceptor ions, such as aluminum ions, at a doping concentration of about 1×10¹⁷ cm⁻³. The presence of the p-type channel adjustment layer 440 may modify the threshold voltage and/or improve the inversion channel mobility of the IGBT 400.

The IGBT 400 further includes n+ connector regions 424 and p+ emitter regions 422 that may be formed by selective implantation of, for example, nitrogen and aluminum, respectively. The n+ connector regions 424 and p+ emitter regions 422 extend through the p-type channel adjustment layer 440 and into the n+ well regions 418. In some embodiments, a distance d between the bottom of the p+ emitter regions 422 and the bottom of the n+ well regions 418 may be about 0.45 μm or more. An increased distance d may provide a lower resistance of the n+ well regions 418, which may result in improved on-state resistance of the IGBT 400.

The IGBT 400 includes a JFET region 420 in the drift layer 416 between adjacent n+ well regions 418. The JFET region 420 may be implanted with p-type dopants to reduce the JFET resistance from the adjacent n+ well regions 418. In some embodiments, the JFET region 420 may be formed by an epitaxial growth process.

The IGBT 400 further includes a gate insulation layer 426, which may include silicon dioxide having a thickness of about 400-1000 Å.

A gate 428 of, for example, polysilicon is formed on the gate insulation layer 426. An interlayer dielectric layer 433 is on the surface of the device 410 and electrically insulates the gate 428.

N-type ohmic contacts 435 are formed to the n+ connector regions 424, and p-type ohmic contacts 437 are formed to the p+ emitter regions 422. The n-type ohmic contacts 435 may include a nickel-based conductive layer, such as Ni and/or NiSi. The p-type ohmic contact 437 may include an aluminum-based conductive layer, such as Al and/or AlSi. A metal overlayer 439 is formed on the interlayer dielectric layer 433 and electrically connects the n-type connector regions 424 and the p-type emitter regions 422 through their respective ohmic contacts 435, 437. An n-type ohmic metal collector contact 432 is formed on the substrate 412.

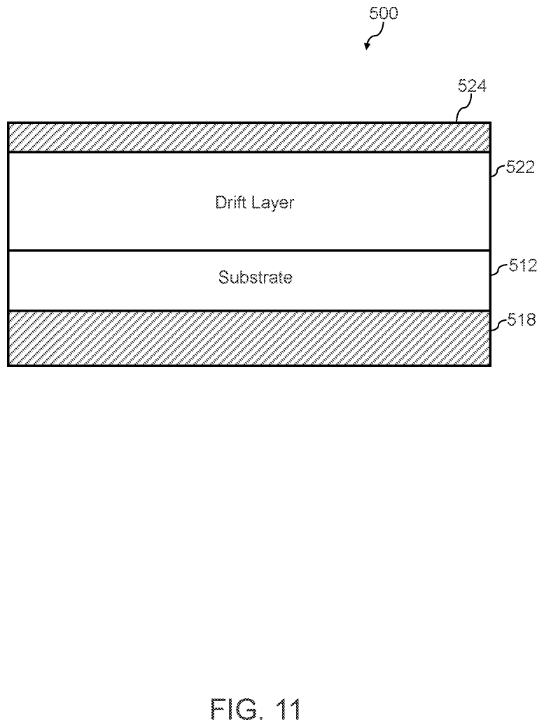

FIG. 11 shows an example power semiconductor device that is a Schottky diode 500. FIG. 11 is intended to represent structures for identification and description and is not intended to represent the structures to physical scale. The Schottky diode 500 may be fabricated from a semiconductor wafer according to example embodiments of the present disclosure and includes a substrate including polycrystalline silicon carbide. The Schottky diode 500 is an example vertical power semiconductor device having a first contact on a wide bandgap epitaxial layer and a second contact on a polycrystalline silicon carbide substrate.

The Schottky diode may include a substrate 512 and a drift layer 522 on the substrate 512. In some examples, the substrate 512 may be a polycrystalline silicon carbide substrate. The drift layer 522 may be fabricated from a silicon carbide epitaxial layer on the polycrystalline silicon carbide substrate. The substrate 512 and drift layer 522 may be fabricated from a semiconductor wafer, such as semiconductor wafer 140 of FIG. 3. In some examples, the substrate 512 may include a polycrystalline silicon carbide substrate and a monocrystalline silicon carbide substrate layer (e.g., 4H monocrystalline silicon carbide substrate layer) on the polycrystalline silicon carbide substrate. The drift layer 522 may be fabricated from a silicon carbide epitaxial layer on the monocrystalline silicon carbide substrate layer. The substrate 512 and drift layer 514 may be fabricated from a semiconductor wafer, such as semiconductor wafer 250 of FIG. 6.

The Schottky diode 500 of FIG. 11 includes a cathode contact 518 on the substrate. The Schottky diode 500 may include an anode contact 524 (e.g., metal stack) on top of the drift layer 522. The anode contact may form a Schottky contact with the drift layer 522.

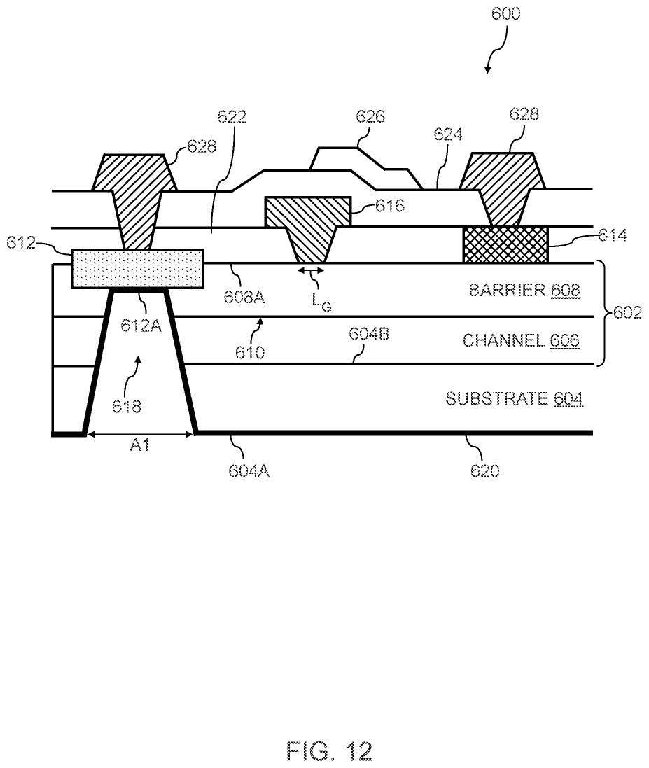

FIG. 12 depicts a cross-sectional view of an example HEMT device 600 according to example embodiments of the present disclosure. FIG. 12 is intended to represent structures for identification and description and is not intended to represent the structures to physical scale. The HEMT device 600 may include a semiconductor structure 602. The semiconductor structure 602 may be a Group III nitride semiconductor structure. The HEMT device 600 is an example lateral power semiconductor device having a first contact on a wide bandgap epitaxial layer and a second contact on the wide bandgap epitaxial layer.

As used herein, the term “Group III nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements can combine with nitrogen to form binary (e.g., GaN), ternary (e.g., AlGaN, AlInN), and quaternary (e.g., AlInGaN) compounds. These compounds all have empirical formulas in which one mole of nitrogen is combined with a total of one mole of the Group III elements. The semiconductor structure 602 may be metal-polar. However, aspects of the present disclosure are applicable to semiconductor devices having N-polar semiconductor structures without deviating from the scope of the present disclosure.

The semiconductor structure 602 may be on a substrate 604. In some examples, the substrate 604 may be a polycrystalline silicon carbide substrate. The semiconductor structure may be fabricated from a Group III-nitride epitaxial layer on the polycrystalline silicon carbide substrate. The substrate 604 and semiconductor structure 602 may be fabricated from a semiconductor wafer, such as semiconductor wafer 140 of FIG. 3. In some examples, the substrate 604 may include a polycrystalline silicon carbide substrate and a monocrystalline silicon carbide substrate layer (e.g., 4H monocrystalline silicon carbide substrate layer) on the polycrystalline silicon carbide substrate. The semiconductor structure 602 may be fabricated from a Group III-nitride epitaxial layer on the monocrystalline silicon carbide substrate layer. The substrate 604 and the semiconductor structure 602 may be fabricated from a semiconductor wafer, such as semiconductor wafer 250 of FIG. 6.

The substrate 604 may have a lower surface 604A and an upper surface 604B. In some embodiments, the substrate 604 of the HEMT device 600 may be a thinned substrate 604. In some embodiments, the thickness of the substrate 604 (e.g., in a vertical Z direction in FIG. 12) may be about 100 μm or less, such as about 75 μm or less, such as about 50 μm or less.

The HEMT device 600 may include a channel layer 606 on the upper surface 604B of the substrate 604 (or on the optional layers described further herein, such as an optional buffer layer or nucleation layer). The HEMT device 600 may include a barrier layer 608 on an upper surface of the channel layer 606. In some embodiments, the channel layer 606 and the barrier layer 608 may each be formed by epitaxial growth. Techniques for epitaxial growth of Group III nitrides have been described in, for example, U.S. Pat. Nos. 5,210,051, 5,393,993, and 5,523,589, the disclosures of which are incorporated by reference herein. The channel layer 606 may have a bandgap that is less than the bandgap of the barrier layer 608. The channel layer 606 may have a larger electron affinity than the barrier layer 608. The channel layer 606 and the barrier layer 608 may include Group III-nitride based materials.

In some embodiments, the channel layer 606 may be a Group III nitride, such as Al_{w}Ga_{1-w}N, where 0≤w<1, provided that the energy of the conduction band edge of the channel layer 606 is less than the energy of the conduction band edge of the barrier layer 608 at the interface between the channel layer 606 and barrier layer 608. In some embodiments, the aluminum mole fraction w is approximately 0, indicating that the channel layer 606 is GaN. The channel layer 606 may or may not include other Group III-nitrides such as InGaN, AlInGaN or the like. The channel layer 606 may be undoped (“unintentionally doped”) and may be grown to a thickness in the range of about 0.5 μm to about 5 μm, such as about 2 μm. The channel layer 606 may be a multi-layer structure, such as a superlattice or combinations of GaN, AlGaN or the like. The channel layer 606 may be under compressive strain in some embodiments.

The semiconductor structure 602 may include a barrier layer 608 on an upper surface of the channel layer 606. The barrier layer 608 may have a bandgap that is different from the bandgap of the channel layer 606. The energy of the conduction band edge of the barrier layer 608 may be greater than the energy of the conduction band edge of the channel layer 606 at the interface between the channel layer 606 and the barrier layer 608. The barrier layer 608 may be a Group III-nitride, such as AlₓGa₁₋ₓN, where x is the aluminum mole fraction in the barrier layer 608. In some embodiments, the aluminum mole fraction x is such that x is in a range of about 0.15 to about 0.40, such as about 0.20 to about 0.25, such as about 0.22 (e.g., the aluminum mole fraction is in a range of 15% to 40%, such as in a range of about 20% to about 25%, such as about 22%), indicating that the barrier layer is an AlGaN layer. The barrier layer 608 may include other Group III elements (e.g., In) without deviating from the scope of the present disclosure. The barrier layer 608, in some examples, may be a multilayer structure. The multilayer structure may include multiple Group III nitride-based layers with differing aluminum mole fractions. The barrier layer 608 may have a thickness in a range of about 10 Angstroms to about 300 Angstroms, such as about 120 Angstroms to about 170 Angstroms, such as about 150 Angstroms.

The channel layer 606 and/or the barrier layer 608 may be deposited, for example, by metal-organic chemical vapor deposition (MOCVD), molecular beam epitaxy (MBE), or hydride vapor phase epitaxy (HVPE). A 2DEG 610 may be induced in the channel layer 606 at an interface between the channel layer 606 and the barrier layer 608. The 2DEG 610 is highly conductive and allows conduction between the source and drain regions of the HEMT device 600.

While the HEMT device 600 is shown with a substrate 604, channel layer 606 and barrier layer 608 for purposes of illustration, the HEMT device 600 may include additional layers/structures/elements. For instance, the HEMT device 600 may include a buffer layer and/or nucleation layer(s) between substrate 604 and the channel layer 606. For example, an AlN buffer layer may be on the upper surface 604B of the substrate 604 to provide an appropriate crystal structure transition between a SiC substrate 604 and the channel layer 606. The optional buffer/nucleation/transition layers may be deposited by MOCVD, MBE, and/or HYPE.

The HEMT device 600 may include a cap layer on the barrier layer 608. HEMT structures including substrates, channel layers, barrier layers, and other layers are discussed by way of example in U.S. Pat. Nos. 5,192,987, 5,296,395, 6,316,793, 6,548,333, 7,544,963, 7,548,112, 7,592,211, 7,615,774, 7,709,269, 7,709,859 and 10,971,612, the disclosures of which are incorporated by reference herein. Additionally, strain balancing transition layer(s) may also and/or alternatively be provided as described, for example, in U.S. Pat. No. 7,030,428, the disclosure of which is incorporated by reference herein.

The HEMT device 600 may include a source contact 612 on an upper surface 608A of the barrier layer 608 or otherwise contacting the barrier layer 608. The HEMT device 600 may include a drain contact 614 on the upper surface 608A of the barrier layer 608 or otherwise contacting the barrier layer 608. The source contact 612 and the drain contact 614 may be laterally spaced apart from each other. In some embodiments, the source contact 612 and the drain contact 614 may include a metal that may form an ohmic contact to a Group III-nitride based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. In some embodiments, the source contact 612 may be an ohmic source contact 612. The drain contact 614 may be an ohmic drain contact 614. Thus, the source contact 612 and/or the drain contact 614 may include an ohmic contact portion in direct contact with the barrier layer 608. In some embodiments, the source contact 612 and/or the drain contact 614 may include a plurality of layers to form an ohmic contact that may be provided as described, for example, in U.S. Pat. Nos. 8,563,372 and 9,214,352, the disclosures of which are incorporated by reference herein.

The HEMT device 600 may include a gate contact 616 on the upper surface 608A of the barrier layer 608 or otherwise contacting the barrier layer 608 (e.g., recessed into the barrier layer 608). The gate contact 616 may have a gate length L_{G}. The gate length L_{G} may be the length of the gate contact 616 at the portion of the gate contact 616 that is on the semiconductor structure 602. In some embodiments, the gate length L_{G} may be in the range of about 100 nm to about 400 nm, such as about 100 nm to about 350 nm. In some embodiments, the gate length L_{G} may be about 100 nm or less, such as about 90 nm or less, such as about 60 nm or less. In some embodiments, the gate length L_{G} may be in a range of about 40 nm to about 90 nm.

The material of the gate contact 616 may be chosen based on the composition of the barrier layer 108, and may, in some embodiments, be a Schottky contact. Materials capable of making a Schottky contact to a Group III-nitride based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSiN).

The source contact 612 may be coupled to a reference signal such as, for example, a ground voltage or other reference signal. The coupling to the reference signal may be provided by a via 618 that extends from a lower surface 604A of the substrate 604, through the substrate 604 and the channel layer 606 to the upper surface 608A of the barrier layer 608. The via 618 may expose a bottom surface of the ohmic portion 612A of the source contact 612. A back metal layer 620 may be on the lower surface 604A of the substrate 604 and on side walls of the via 618. The back metal layer 620 may directly contact the ohmic portion 612A of the source contact 612. In some embodiments a contact area between the back metal layer 620 and the bottom surface of the ohmic portion 612A of the source contact 612 may be fifty percent or more of an area of the bottom surface of the ohmic portion 612A of the source contact 612. Thus, the back metal layer 620, and a signal coupled thereto, may be electrically connected to the source contact 612.

In some embodiments, the via 618 may have an oval or circular cross-section when viewed in a plan view. However, the present disclosure is not limited thereto. In some embodiments, a cross-section of the via 618 may be a polygon or other shape, as will be understood by one of ordinary skill in the art using the disclosures provided herein.

Depending on the embodiment, the drain contact 614 may be formed on, in and/or through the barrier layer 608, and there can be ion implantation into the materials around the drain contact 614 (e.g., through the barrier layer 608 and into the channel layer 606) to reduce resistivity and provide improved ohmic contact to the semiconductor material. In yet other embodiments, there is no source via 618, and the source contact 612 is formed on, in and/or through the barrier layer 608, and there can be ion implantation in the materials around the source contact 612 to reduce resistivity and provide improved ohmic contact to the semiconductor material. In some examples, the connections to the source contact 612, drain contact 614, and/or gate contact 616 can be made from the top and/or the bottom to provide for flip chip configuration of the HEMT device 600. In some examples, thermal paths may be provided from the top and/or bottom to provide for flip chip configuration of the HEMT device 600.

The HEMT device 600 may include a first insulating layer 622. The first insulating layer 622 may directly contact the upper surface of the semiconductor structure 602 (e.g., contact the upper surface 608A of the barrier layer 608). The HEMT device 600 may include a second insulating layer 624. The second insulating layer 624 may be on the first insulating layer 622. It will also be appreciated that more than two insulating layers may be included in some embodiments. The first insulating layer 622 and/or the second insulating layer 624 may serve as passivation layers for the HEMT device 600. The first insulating layer 622 and/or the second insulating layer 624 may be dielectric layers. Different dielectric materials may be used such as a SiN, SiO2, Al₂O₃, MgOx, MgNx, ZnO, SiNx, SiOx, alloys or layer sequences thereof, or epitaxial materials.

The source contact 612, the drain contact 614, and the gate contact 616 may be in the first insulating layer 622. In some embodiments, at least a portion of the gate contact 616 may be on the first insulating layer 622. In some embodiments, the gate contact 616 may be a T-shaped gate and/or a gamma gate, the formation of which is discussed by way of example in U.S. Pat. Nos. 8,049,252, 7,045,404, and 8,120,064, the disclosures of which are incorporated by reference herein. The second insulating layer 624 may be on the first insulating layer 622 and on portions of the source contact 612, drain contact 614, and gate contact 616. The protrusions from the gate can also be referred to as a field plate integrated with the gate.

A field plate 626 may be on the second insulating layer 624 as illustrated in FIG. 12, or on another insulating layer depending on the number of insulating layers included in the HEMT device. At least a portion of a field plate 626 may be at least partially overlapping the gate contact 616. At least a portion of the field plate 126 may be on a portion of the second insulating layer 624 that is between the gate contact 616 and the drain contact 614. The field plate 626 may reduce the peak electric field in the HEMT device 600, which may result in increased breakdown voltage and reduced charge trapping. The reduction of the electric field can also yield other benefits such as reduced leakage currents and enhanced reliability. Field plates and techniques for forming field plates are discussed, by way of example, in U.S. Pat. No. 8,120,064, the disclosure of which is incorporated by reference herein.

Metal contacts 628 may be disposed in the second insulating layer 624 as illustrated in FIG. 12, or on another insulating layer depending on the number of insulating layers included in the HEMT device. The metal contacts 628 may provide interconnection between the source contact 612 and other parts of the HEMT device 600, or may provide interconnection between the drain contact 614, and other parts of the HEMT device 600. Respective ones of the metal contacts 628 may directly contact respective ones of the drain contact 614 and/or source contact 612. The metal contacts 628 may include metal or other highly conductive material, including, for example, copper, cobalt, gold, and/or a composite metal.

A HEMT transistor may be formed by the active region between the source contact 612 and the drain contact 614 under the control of a gate contact 616 between the source contact 612 and the drain contact 614. FIG. 12 depicts a cross-sectional view of one unit of an HEMT device 600 for purposes of illustration. The HEMT device 600 may be formed adjacent to additional HEMT device units and may share, for instance, a source contact 612 with adjacent HEMT device units.

Example aspects of the present disclosure are set forth below. Any of the below features or examples may be used in combination with any of the embodiments or features provided in the present disclosure.

One example aspect of the present disclosure is directed to a wide bandgap semiconductor wafer. The wide bandgap semiconductor wafer includes a polycrystalline silicon carbide substrate. The wide bandgap semiconductor wafer includes a wide bandgap epitaxial layer on the polycrystalline silicon carbide substrate.

In some examples, the wide bandgap epitaxial layer comprises a silicon carbide epitaxial layer.

In some examples, the wide bandgap epitaxial layer comprises a Group III-nitride epitaxial layer.

In some examples, the wide bandgap epitaxial layer comprises a gallium nitride epitaxial layer.

In some examples, the wide bandgap epitaxial layer is attached to the polycrystalline silicon carbide substrate.

In some examples, the wide bandgap epitaxial layer is plasma bonded to the polycrystalline silicon carbide substrate.

In some examples, the wide bandgap epitaxial layer is directly on the polycrystalline silicon carbide substrate such that there are no intervening structures between the wide bandgap epitaxial layer and the polycrystalline silicon carbide substrate.

In some examples, the polycrystalline silicon carbide substrate has a thickness in a range of about 1 μm to about 1000 μm.

In some examples, the polycrystalline silicon carbide substrate has a thickness in a range of about 150 μm to about 500 μm.

In some examples, the wide bandgap epitaxial layer has a thickness in a range of about 0.2 μm to about 200 μm.

In some examples, the polycrystalline silicon carbide substrate comprises an n-type polycrystalline silicon carbide substrate.

In some examples, the polycrystalline silicon carbide substrate comprises an unintentionally doped polycrystalline silicon carbide substrate.

In some examples, the polycrystalline silicon carbide substrate comprises a diameter of about 150 mm or greater.

In some examples, the polycrystalline silicon carbide substrate comprises a diameter in a range of about 150 mm to about 300 mm.

In some examples, the semiconductor wafer includes a monocrystalline silicon carbide substrate layer between the polycrystalline silicon carbide substrate and the wide bandgap epitaxial layer.

In some examples, the monocrystalline silicon carbide substrate layer is directly on the polycrystalline silicon carbide substrate such that there are no intervening structures between the polycrystalline silicon carbide substrate and the monocrystalline silicon carbide substrate layer.

In some examples, the monocrystalline silicon carbide substrate layer is a 4H silicon carbide layer.

In some examples, the monocrystalline silicon carbide substrate layer has a thickness in range of about 10 μm to about 100 μm.

In some examples, the monocrystalline silicon carbide substrate layer is attached to the polycrystalline silicon carbide substrate.

In some examples, the monocrystalline silicon carbide substrate layer is plasma bonded to the polycrystalline silicon carbide substrate.

Some examples are directed to a wide bandgap semiconductor device including at least a portion of the semiconductor wafer according to an of the examples disclosed herein.

In some examples, the wide bandgap semiconductor device is a transistor or a diode.

In some examples, the wide bandgap semiconductor device is a MOSFET, IGBT, HEMT, or a Schottky diode.

Another example aspect of the present disclosure is directed to a method. The method includes providing a wide bandgap epitaxial layer on a first substrate. The method includes providing the wide bandgap epitaxial layer on a second substrate (e.g., polycrystalline silicon carbide substrate). The method includes separating the first substrate from the wide bandgap epitaxial layer such that at least a portion of the wide bandgap epitaxial layer remains on the second substrate.

In some examples, the first substrate is a sapphire substrate.

In some examples, providing the second substrate comprises a polycrystalline silicon carbide substrate.

In some examples, providing the wide bandgap epitaxial layer on a first substrate comprises providing the wide bandgap epitaxial layer on a buffer layer on the first substrate, the buffer layer being an epitaxial layer.

In some examples, the buffer layer comprises aluminum nitride.

In some examples, providing the wide bandgap epitaxial layer on the second substrate comprises plasma bonding the wide bandgap epitaxial layer to the second substrate.

In some examples, separating the first substrate from the wide bandgap epitaxial layer comprises: inducing a cleavage plane in the wide bandgap epitaxial layer; and separating the first substrate from the wide bandgap epitaxial layer along the cleavage plane.

In some examples, inducing a cleavage plane comprises emitting one or more lasers into the wide bandgap epitaxial layer.

In some examples, inducing a cleavage plane comprising implanting one or more species into the wide bandgap epitaxial layer.

In some examples, the wide bandgap epitaxial layer comprises a silicon carbide epitaxial layer.

In some examples, the wide bandgap epitaxial layer comprises a Group III-nitride epitaxial layer.

In some examples, the method includes fabricating one or more devices at least partially in the wide bandgap epitaxial layer.

In some examples, the one or more devices comprises a transistor device or a diode.

In some examples, the one or more devices comprises a MOSFET, an IGBT, a JFET, a Schottky diode, or an HEMT.

Another example aspect of the present disclosure is directed to a method. The method includes providing a monocrystalline silicon carbide substrate layer on a substrate (e.g., polycrystalline silicon carbide substrate). The method includes separating a portion of the monocrystalline silicon carbide substrate layer such that at least a portion of the monocrystalline silicon carbide substrate layer remains on the substrate. The method includes providing a wide bandgap epitaxial layer on the monocrystalline silicon carbide substrate layer.

In some examples providing a monocrystalline silicon carbide substrate layer on a substrate comprises: providing the monocrystalline silicon carbide substrate layer on a first substrate to provide a first substrate assembly; providing the monocrystalline silicon carbide substrate layer of the first substrate assembly on the substrate.

In some examples, separating a portion of the monocrystalline silicon carbide substrate layer comprises separating the first substrate assembly from the substrate such that a portion of the monocrystalline silicon carbide substrate layer remains on the substrate.

In some examples providing the monocrystalline silicon carbide substrate layer on the first substrate comprises attaching the monocrystalline silicon carbide substrate layer to the first substrate.

In some examples, providing the monocrystalline silicon carbide substrate layer on the substrate comprises: prior to providing the monocrystalline silicon carbide substrate layer of the first substrate assembly on the substrate, separating a portion of the monocrystalline silicon carbide substrate layer from the first substrate such that a portion of the monocrystalline silicon carbide substrate layer remains on the first substrate.

In some examples, the first substrate is a sapphire substrate.

In some examples, providing the monocrystalline silicon carbide substrate layer on the first substrate comprises providing the monocrystalline silicon carbide substrate layer on a buffer layer on the first substrate.

In some examples, the buffer layer is an epitaxial layer.

In some examples, the buffer layer comprises aluminum nitride.

In some examples, attaching the monocrystalline silicon carbide substrate layer to the polycrystalline silicon carbide substrate comprises plasma bonding the monocrystalline silicon carbide substrate layer to the substrate.

In some examples, separating a portion of the monocrystalline silicon carbide substrate layer such that at least a portion of the monocrystalline silicon carbide substrate layer remains on the substrate comprises: inducing a cleavage plane in the monocrystalline silicon carbide substrate layer; and separating the portion of the monocrystalline silicon carbide substrate layer along the cleavage plane.

In some examples, the monocrystalline silicon carbide substrate layer comprises a 4H silicon carbide layer.

In some examples, the wide bandgap epitaxial layer comprises a silicon carbide epitaxial layer.

In some examples, the wide bandgap epitaxial layer comprises a Group III-nitride epitaxial layer.

In some examples, the method includes fabricating one or more devices at least partially in the wide bandgap epitaxial layer.

In some examples, the one or more devices comprises a transistor device or a diode.

In some examples, the one or more devices comprises a MOSFET, an IGBT, a JFET, a Schottky diode, or an HEMT.

Another example aspect of the present disclosure is directed to a semiconductor device. The semiconductor device includes a polycrystalline silicon carbide substrate. The semiconductor device includes a wide bandgap epitaxial layer on the polycrystalline silicon carbide substrate. At least a portion of the wide bandgap epitaxial layer comprises a structure forming a part of a transistor or a diode.

In some examples, the semiconductor device is a vertical power semiconductor device having a first contact on the wide bandgap epitaxial layer and a second contact on the polycrystalline silicon carbide substrate.

In some examples, the semiconductor device includes a gate contact on the wide bandgap epitaxial layer.

In some examples, the semiconductor device is a lateral power semiconductor device having a first contact and a second contact on the wide bandgap epitaxial layer.

In some examples, the semiconductor device includes gate contact on the wide bandgap epitaxial layer.

In some examples, the wide bandgap epitaxial layer comprises a silicon carbide epitaxial layer.

In some examples, the wide bandgap epitaxial layer comprises a Group III-nitride epitaxial layer.

In some examples, the wide bandgap epitaxial layer is attached to the polycrystalline silicon carbide substrate.

In some examples, the wide bandgap epitaxial layer is plasma bonded to the polycrystalline silicon carbide substrate.

In some examples, the wide bandgap epitaxial layer is directly on the polycrystalline silicon carbide substrate such that there are no intervening structures between the wide bandgap epitaxial layer and the polycrystalline silicon carbide substrate.

In some examples, the polycrystalline silicon carbide substrate has a thickness in a range of about 1 μm to about 1000 μm.

In some examples, the wide bandgap epitaxial layer has a thickness in a range of about 0.2 μm to about 200 μm.

In some examples, the polycrystalline silicon carbide substrate comprises an n-type polycrystalline silicon carbide substrate.

In some examples, the polycrystalline silicon carbide substrate comprises an unintentionally doped polycrystalline silicon carbide substrate.

In some examples, the device includes a monocrystalline silicon carbide substrate layer between the polycrystalline silicon carbide substrate and the wide bandgap epitaxial layer.

In some examples, the monocrystalline silicon carbide substrate layer is a 4H silicon carbide layer.

In some examples, the monocrystalline silicon carbide substrate layer has a thickness in range of about 10 μm to about 100 μm.

In some examples, the monocrystalline silicon carbide substrate layer is attached to the polycrystalline silicon carbide substrate.

In some examples, the monocrystalline silicon carbide substrate layer is plasma bonded to the polycrystalline silicon carbide substrate.

In some examples, the semiconductor device is a MOSFET.

In some examples, the semiconductor device is a Schottky diode.

In some examples, the semiconductor device is a JFET.

In some examples, the semiconductor device is an HEMT.

Another example aspect of the present disclosure is directed to a wide bandgap semiconductor wafer. The wide bandgap semiconductor wafer includes a sapphire substrate. The wide bandgap semiconductor wafer includes a silicon carbide epitaxial layer on the sapphire substrate.

In some examples, the semiconductor wafer comprises a buffer layer between the sapphire substrate and the silicon carbide epitaxial layer.

In some examples, the buffer layer comprises aluminum nitride.

In some examples, the buffer layer is an epitaxial layer.

In some examples, the sapphire substrate has a thickness in a range of about 100 μm to about 1000 μm.

In some examples, the silicon carbide epitaxial layer has a thickness in a range of about 0.2 μm to about 200 μm.

In some examples, the silicon carbide epitaxial layer comprises a monocrystalline silicon carbide layer.

In some examples, the monocrystalline silicon carbide layer comprises a 4H silicon carbide layer.

In some examples, the 4H silicon carbide layer has a thickness of less than about 100 μm or less.

In some examples, the 4H silicon carbide layer has a thickness of less than about 20 μm or less.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1.-37. (canceled)

38. A method, comprising:
providing a monocrystalline silicon carbide substrate layer on a substrate;
separating a portion of the monocrystalline silicon carbide substrate layer such that at least a portion of the monocrystalline silicon carbide substrate layer remains on the substrate; and
providing a wide bandgap epitaxial layer on the monocrystalline silicon carbide substrate layer.

39.-54. (canceled)

55. A semiconductor device, comprising:
a polycrystalline silicon carbide substrate;
a wide bandgap epitaxial layer on the polycrystalline silicon carbide substrate; and
wherein at least a portion of the wide bandgap epitaxial layer comprises a structure forming a part of a transistor or a diode.

56. The semiconductor device of claim 55, wherein the semiconductor device is a vertical power semiconductor device having a first contact on the wide bandgap epitaxial layer and a second contact on the polycrystalline silicon carbide substrate.

57. The semiconductor device of claim 56, further comprising a gate contact on the wide bandgap epitaxial layer.

58. The semiconductor device of claim 55, wherein the semiconductor device is a lateral power semiconductor device having a first contact and a second contact on the wide bandgap epitaxial layer.

59. The semiconductor device of claim 58, further comprising a gate contact on the wide bandgap epitaxial layer.

60. The semiconductor device of claim 55, wherein the wide bandgap epitaxial layer comprises a silicon carbide epitaxial layer.

61. The semiconductor device of claim 55, wherein the wide bandgap epitaxial layer comprises a Group III-nitride epitaxial layer.

62. The semiconductor device of claim 55, wherein the wide bandgap epitaxial layer is attached to the polycrystalline silicon carbide substrate.

63. The semiconductor device of claim 55, wherein the wide bandgap epitaxial layer is plasma bonded to the polycrystalline silicon carbide substrate.

64. The semiconductor device of claim 55, wherein the wide bandgap epitaxial layer is directly on the polycrystalline silicon carbide substrate such that there are no intervening structures between the wide bandgap epitaxial layer and the polycrystalline silicon carbide substrate.

65. The semiconductor device of claim 55, wherein the polycrystalline silicon carbide substrate has a thickness in a range of about 1 μm to about 1000 μm.

66. The semiconductor device of claim 55, wherein the wide bandgap epitaxial layer has a thickness in a range of about 0.2 μm to about 200 μm.

67. (canceled)

68. The semiconductor device of claim 55, wherein the polycrystalline silicon carbide substrate comprises an unintentionally doped polycrystalline silicon carbide substrate.

69. The semiconductor device of claim 55, further comprising a monocrystalline silicon carbide substrate layer between the polycrystalline silicon carbide substrate and the wide bandgap epitaxial layer.

70. The semiconductor device of claim 69, wherein the monocrystalline silicon carbide substrate layer is a 4H silicon carbide layer.

71.-73. (canceled)

74. The semiconductor device of claim 55, wherein the semiconductor device is a MOSFET.

75. The semiconductor device of claim 55, wherein the semiconductor device is a Schottky diode.

76. The semiconductor device of claim 55, wherein the semiconductor device is a JFET.

77. The semiconductor device of claim 55, wherein the semiconductor device is an HEMT.

78.-87. (canceled)
